(19) United States
(12) Patent Application Publication
(10) Pub. No.: US 2025/0072263 A1
(43) Pub. Date: Feb. 27, 2025

(54) DISPLAY DEVICE

(71) Applicant: Samsung Display Co., LTD., Yongin-si (KR)

(72) Inventors: Cheon Deok PARK, Yongin-si (KR); Dong Min KIM, Yongin-si (KR); Jung Tae KIM, Yongin-si (KR); Jun Ho CHOI, Yongin-si (KR)

(21) Appl. No.: 18/618,967

(22) Filed: Mar. 27, 2024

(30) Foreign Application Priority Data
Aug. 21, 2023 (KR) 10-2023-0109028

(51) Int. Cl. H10K 59/80; H10K 59/124

(52) U.S. Cl. CPC H10K 59/873; H10K 59/124

(57) ABSTRACT

A display device includes: a support substrate including a main area including a display area in which light emitting areas are arranged, a hole area surrounded by the main area, and a hole peripheral area between the hole area and the main area; a circuit layer on the support substrate; an element layer on the circuit layer; a capping layer on the element layer; an encapsulation substrate on the capping layer and bonded to the support substrate; a first hole peripheral dam in the hole peripheral area and surrounding a periphery of the hole area; a second hole peripheral dam in the hole peripheral area and surrounding a periphery of the first hole peripheral dam; and an auxiliary dam in a valley area of the hole peripheral area between the first hole peripheral dam and the second hole peripheral dam.

### CROSS-REFERENCE TO RELATED APPLICATION

The present application claims priority to and the benefit of Korean Patent Application No. 10-2023-0109028, filed on Aug. 21, 2023, in the Korean Intellectual Property Office, the entire disclosure of which is incorporated herein by reference.

### BACKGROUND

### 1. Field

Aspects of some embodiments of the present disclosure relate to a display device and a method of manufacturing the same.

### 2. Description of the Related Art

As an information society develops, consumer demand for a display device for displaying images is increasing in various forms. For example, display devices have been applied to various electronic devices such as smartphones, digital cameras, laptop computers, navigation devices, and smart televisions.

Display devices include flat panel display devices such as a liquid crystal display devices, field emission display devices, or light emitting display devices. Here, light emitting display devices may include organic light emitting display devices including an organic light emitting element, an inorganic light emitting display device including an inorganic light emitting element such as an inorganic semiconductor, and a micro or nano light emitting display device including a micro or nano light emitting element.

Organic light emitting display device display images using a plurality of light emitting elements each including a light emitting layer made of an organic material. As such, as the organic light emitting display device implements images displayed using self-light emitting elements, organic light emitting display devices may have relatively superior performance in terms of power consumption, response speed, emission efficiency, luminance, and wide viewing angle compared to other display devices.

The above information disclosed in this Background section is only for enhancement of understanding of the background and therefore the information discussed in this Background section does not necessarily constitute prior art.

### SUMMARY

According to some embodiments of the present disclosure, a support substrate of a display device may include a main area including a display area in which light emitting areas are arranged, a hole area surrounded by the main area, and a hole peripheral area between the hole area and the main area.

A display device may include a light transmitting hole in the hole area and a hole filling layer that fills the light transmitting hole.

If the hole filling layer extends into the display area, a display quality around the hole area may deteriorate due to a decrease in luminance caused by the hole filling layer. Accordingly, because the hole filling layer is not in at least a portion of the hole peripheral area adjacent to the display area, according to some embodiments, a sagging defect of an encapsulation substrate may occur in the hole peripheral area.

In addition, due to the excessive sagging defect of the encapsulation substrate, the lifting defect of the encapsulation substrate may occur in a portion of the display area adjacent to the hole peripheral area.

Aspects of some embodiments of the present disclosure include a display device in which the sagging defect of an encapsulation substrate may be relatively reduced in a hole peripheral area.

According to some embodiments of the present disclosure, a display device includes a support substrate including a main area including a display area in which light emitting areas are arranged, a hole area surrounded by the main area, and a hole peripheral area between the hole area and the main area; a circuit layer on the support substrate; an element layer on the circuit layer; a capping layer on the element layer; an encapsulation substrate on the capping layer and bonded to the support substrate; a first hole peripheral dam in the hole peripheral area and surrounding a periphery of the hole area; a second hole peripheral dam in the hole peripheral area and surrounding a periphery of the first hole peripheral dam; and an auxiliary dam in a valley area of the hole peripheral area between the first hole peripheral dam and the second hole peripheral dam.

According to some embodiments, the second hole peripheral dam is adjacent to the main area. According to some embodiments, the auxiliary dam is closer to the second hole peripheral dam among the first hole peripheral dam and the second hole peripheral dam.

According to some embodiments, the first hole peripheral dam is arranged in a ring shape surrounding the periphery of the hole area. According to some embodiments, the auxiliary dam is arranged in a ring shape surrounding the periphery of the first hole peripheral dam. According to some embodiments, the second hole peripheral dam is arranged in a ring shape surrounding a periphery of the auxiliary dam.

According to some embodiments, the auxiliary dam includes dot-shaped pillars arranged along the periphery of the first hole peripheral dam and spaced apart from each other.

According to some embodiments, the display device further comprises a light transmitting hole in the hole area and penetrating through the circuit layer, the element layer, and the capping layer; and a hole filling layer in an area surrounded by the first hole peripheral dam and filling the light transmitting hole.

According to some embodiments, a portion of the hole filling layer extends to an area between the first hole peripheral dam and the auxiliary dam.

According to some embodiments, the circuit layer includes a buffer layer covering the support substrate; a gate insulating layer covering a semiconductor layer on the buffer layer; an interlayer insulating layer covering a first conductive layer on the gate insulating layer; a first planarization layer covering a second conductive layer on the interlayer insulating layer; and a second planarization layer covering the first planarization layer. According to some embodiments, the element layer includes anode electrodes respectively in the light emitting areas of the display area; a pixel defining layer in a non-light emitting area, which is a spaced area between the light emitting areas, of the display area and covering an edge of each of the anode electrodes; a spacer layer on a portion of the pixel defining layer; light emitting layers on the anode electrodes; and a cathode electrode on the light emitting layers, the pixel defining layer, and the spacer layer. According to some embodiments, the capping layer covers the cathode electrode. According to some embodiments, the first hole peripheral dam, the second hole peripheral dam, and the auxiliary dam each include a structure in which at least one dam layer is stacked on the first planarization layer. According to some embodiments, at least one dam layer of the first hole peripheral dam is on a same layer as at least one of the second planarization layer, the pixel defining layer, or the spacer layer. According to some embodiments, at least one dam layer of the second hole peripheral dam is on a same layer as at least one of the second planarization layer, the pixel defining layer, or the spacer layer.

According to some embodiments, a thickness of the auxiliary dam is less than or equal to a thickness of the second hole peripheral dam. According to some embodiments, the encapsulation substrate is in contact with the capping layer and is supported by the auxiliary dam in the valley area.

According to some embodiments, at least one dam layer of the auxiliary dam is on a same layer as at least one dam layer of the second hole peripheral dam.

According to some embodiments, at least one dam layer of the auxiliary dam is on a same layer as at least one of the pixel defining layer or the spacer layer.

According to some embodiments, the first planarization layer and the second planarization layer are prepared together through a single mask process. According to some embodiments, the pixel defining layer and the spacer layer are prepared together through a single mask process.

According to some embodiments of the present disclosure, a display device includes a support substrate including a main area including a display area in which light emitting areas are arranged, a hole area surrounded by the main area, and a hole peripheral area between the hole area and the main area; a circuit layer on the support substrate; an element layer on the circuit layer; a capping layer on the element layer; an encapsulation substrate on the capping layer and bonded to the support substrate; a first hole peripheral dam in the hole peripheral area and surrounding a periphery of the hole area; a second hole peripheral dam in the hole peripheral area and surrounding a periphery of the first hole peripheral dam; an auxiliary dam in a valley area of the hole peripheral area between the first hole peripheral dam and the second hole peripheral dam; a light transmitting hole in the hole area and penetrating through the circuit layer, the element layer, and the capping layer; and a hole filling layer in an area surrounded by the first hole peripheral dam and filling the light transmitting hole.

According to some embodiments, a thickness of the auxiliary dam is less than or equal to a thickness of the second hole peripheral dam. According to some embodiments, the encapsulation substrate is in contact with the capping layer and is supported by the auxiliary dam in the valley area.

According to some embodiments, the circuit layer includes a buffer layer covering the support substrate; a gate insulating layer covering a semiconductor layer on the buffer layer; an interlayer insulating layer covering a first conductive layer on the gate insulating layer; a first planarization layer covering a second conductive layer on the interlayer insulating layer; and a second planarization layer covering the first planarization layer. According to some embodiments, the element layer includes anode electrodes respectively in the light emitting areas of the display area; a pixel defining layer in a non-light emitting area, which is a spaced area between the light emitting areas, of the display area and covering an edge of each of the anode electrodes; a spacer layer on a portion of the pixel defining layer and spaced apart from each other; light emitting layers on the anode electrodes; and a cathode electrode on the light emitting layers, the pixel defining layer, and the spacer layer. According to some embodiments, the capping layer covers the cathode electrode. According to some embodiments, the first hole peripheral dam, the second hole peripheral dam, and the auxiliary dam each include a structure in which at least one dam layer is stacked on the first planarization layer. According to some embodiments, at least one dam layer of the first hole peripheral dam is on the same layer as at least one of the second planarization layer, the pixel defining layer, or the spacer layer. According to some embodiments, at least one dam layer of the second hole peripheral dam is on the same layer as at least one of the second planarization layer, the pixel defining layer, or the spacer layer.

According to some embodiments, at least one dam layer of the auxiliary dam is on a same layer as at least one dam layer of the second hole peripheral dam.

According to some embodiments, at least one dam layer of the auxiliary dam is on a same layer as at least one of the pixel defining layer or the spacer layer.

According to some embodiments, the second hole peripheral dam is adjacent to the main area. According to some embodiments, the auxiliary dam is closer to the second hole peripheral dam among the first hole peripheral dam and the second hole peripheral dam.

According to some embodiments, the first hole peripheral dam is arranged in a ring shape surrounding the periphery of the hole area. According to some embodiments, the auxiliary dam is arranged in a ring shape surrounding the periphery of the first hole peripheral dam. According to some embodiments, the second hole peripheral dam is arranged in a ring shape surrounding a periphery of the auxiliary dam.

According to some embodiments, the auxiliary dam includes dot-shaped pillars arranged along the periphery of the first hole peripheral dam and spaced apart from each other.

According to some embodiments, the first planarization layer and the second planarization layer are prepared together through a single mask process. According to some embodiments, the pixel defining layer and the spacer layer are prepared together through a single mask process.

According to some embodiments, the display device includes a support substrate, a circuit layer, an element layer, a capping layer, and an encapsulation substrate. According to some embodiments, the support substrate includes a main area including light emitting areas, a hole area surrounded by the main area, and a hole peripheral area between the hole area and the main area.

According to some embodiments, the display device further includes a first hole peripheral dam in the hole peripheral area and surrounding a periphery of the hole area, a second hole peripheral dam in the hole peripheral area and surrounding a periphery of the first hole peripheral dam, and an auxiliary dam in a valley area of the hole peripheral area between the first hole peripheral dam and the second hole peripheral dam.

According to some embodiments, the display device further includes a light transmitting hole in the hole area and penetrating through the circuit layer, the element layer, and the capping layer, and a hole filling layer in an area surrounded by the first hole peripheral dam and filling the light transmitting hole.

According to some embodiments, the valley area between the first hole peripheral dam and the second hole peripheral dam may prevent the hole filling layer from extending into the display area. As a result, degradation of display quality of a portion of the display area adjacent to the hole peripheral area by the hole filling layer may be prevented or reduced.

Further, according to some embodiments, because the encapsulation substrate may be supported by the auxiliary dam in the valley area of the hole peripheral area between the first hole peripheral area and the second hole peripheral area, the sagging defect in the encapsulation substrate that occurs in the hole peripheral area may be reduced.

In addition, as the sagging defect of the encapsulation substrate is reduced, the lifting defect of the encapsulation substrate that occurs in a portion of the display area adjacent to the hole peripheral area may also be prevented.

Therefore, because a surface of the encapsulation substrate may be prevented from becoming uneven in the hole peripheral area and a portion of the display area adjacent thereto, the display quality of the display device may be relatively improved.

However, the characteristics of embodiments according to the present disclosure are not limited to those described above and various other characteristics are incorporated herein.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a perspective view illustrating a display device according to some embodiments;

FIG. 2 is a plan view illustrating the display device of FIG. 1;

FIG. 3 is a cross-sectional view taken along the line A-A′ of FIG. 2;

FIG. 4 is a layout view illustrating portion B of FIG. 2;

FIG. 5 is an equivalent circuit diagram illustrating an example of a light emitting pixel driver of FIG. 4 according to some embodiments;

FIG. 6 is a cross-sectional view taken along the line D-D′ of FIG. 4;

FIG. 7 is a layout view illustrating portion C of FIG. 2 according to some embodiments;

FIG. 8 is a cross-sectional view taken along line E-E′ of FIG. 7 according to some embodiments;

FIG. 9 is a cross-sectional view illustrating a hole area and a hole peripheral area according to a comparative example;

FIG. 10 is a cross-sectional view taken along line E-E′ of FIG. 7 according to some embodiments;

FIG. 11 is a cross-sectional view illustrating a function of an auxiliary dam according to some embodiments; and

FIG. 12 is a layout view illustrating portion C of FIG. 2 according to some embodiments.

### DETAILED DESCRIPTION

Aspects of some embodiments of the present disclosure will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Description of some of the parts or components that are not necessary to enable a person having ordinary skill in the art to understand, make, and/or use embodiments according to the present disclosure may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and/or vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the spirit and scope of the present disclosure herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A or B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, aspects of some embodiments will be described more fully with reference to the accompanying drawings.

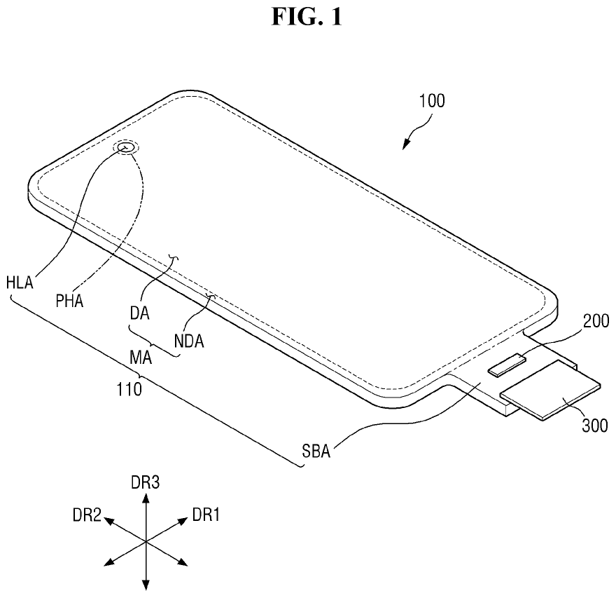

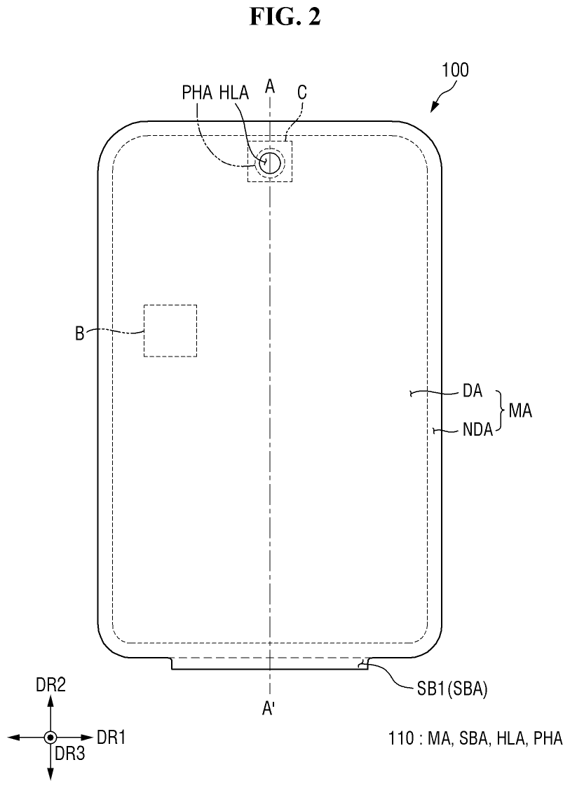

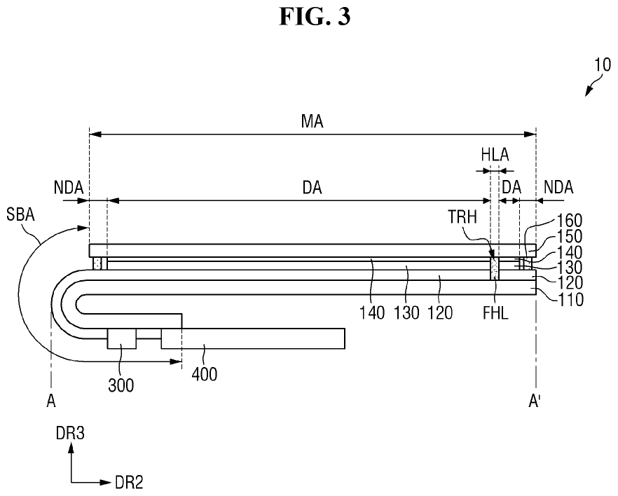

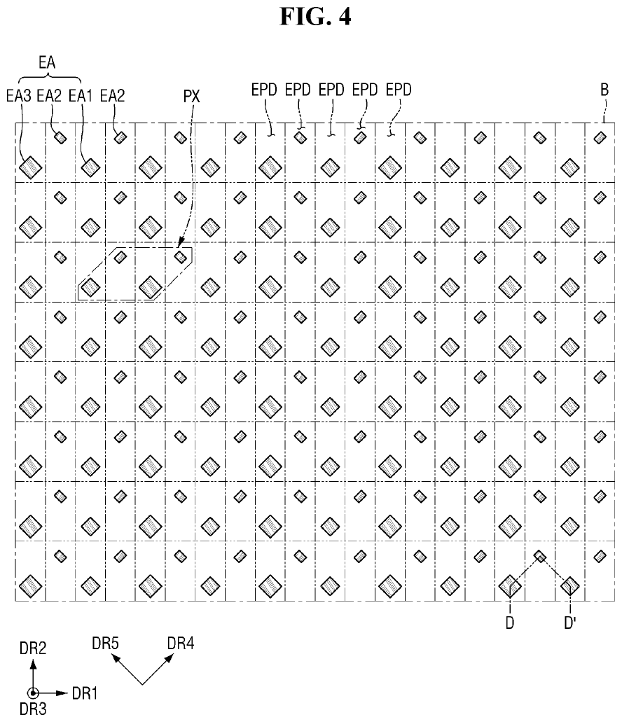

FIG. 1 is a perspective view illustrating a display device according to some embodiments. FIG. 2 is a plan view illustrating the display device of FIG. 1. FIG. 3 is a cross-sectional view taken along the line A-A′ of FIG. 2. FIG. 4 is a layout view illustrating further details of the portion B of FIG. 2.

Referring to FIGS. 1 and 2, a display device 100 is a device that displays moving images or still images, and may be used as a display screen for various products such as televisions, laptop computers, monitors, billboards, and Internet of Things (IOT) devices as well as portable electronic devices such as mobile phones, smartphones, tablet personal computers (PCs), smartwatches, watch phones, mobile communication terminals, electronic organizers, electronic books, portable multimedia players (PMPs), navigation devices, and ultra mobile PCs (UMPCs). Embodiments according to the present disclosure are not limited thereto, and according to some embodiments, the display device 100 may be incorporated into any suitable electronic device configured to display images.

The display device 100 may be a light emitting display device such as an organic light emitting display device using an organic light emitting diode, a quantum dot light emitting display device including a quantum dot light emitting layer, an inorganic light emitting display device including an inorganic semiconductor, and a micro light emitting display device using a micro or nano light emitting diode (micro or nano LED). Hereinafter, the description will be made mainly in the context of the display device 100 is an organic light emitting display device, for convenience of description. However, embodiments according to the present disclosure are not limited thereto and may be applied to display devices including organic insulating materials, organic light emitting materials, and metal materials.

The display device 100 may be formed to be flat, but embodiments according to the present disclosure are not limited thereto. For example, the display device 100 may include curved surface portions formed at left and right distal ends thereof and having a constant curvature or a variable curvature. In addition, the display device 100 may be flexible, or flexibly formed, to be curved, bent, folded, or rolled, without damaging the display device 100.

As illustrated in FIGS. 1, 2, and 3, the display device 100 includes a support substrate 110.

The support substrate 110 may include a main area MA corresponding to a display surface of the display device 100, a hole area HLA surrounded by the main area MA, and a hole peripheral area PHA located between the main area MA and the hole area HLA.

The main area MA may include a display area DA located at the center and a non-display area NDA located around (e.g., in a periphery, or outside a footprint of) the display area DA.

The display area DA may be formed in a rectangular plane having a short side in a first direction DR1 and a long side in a second direction DR2 intersecting the first direction DR1. A corner where the short side in the first direction DR1 and the long side in the second direction DR2 meet may be rounded to have a curvature (e.g., a set or predetermined curvature) or may be formed at a right angle. The planar shape of the display area DA is not limited to the quadrangular shape, and the display area DA may be formed in other polygonal, circular, or oval shapes.

The non-display area NDA may be located at an edge of the main area MA to surround (e.g., in a periphery or outside a footprint of) the display area DA.

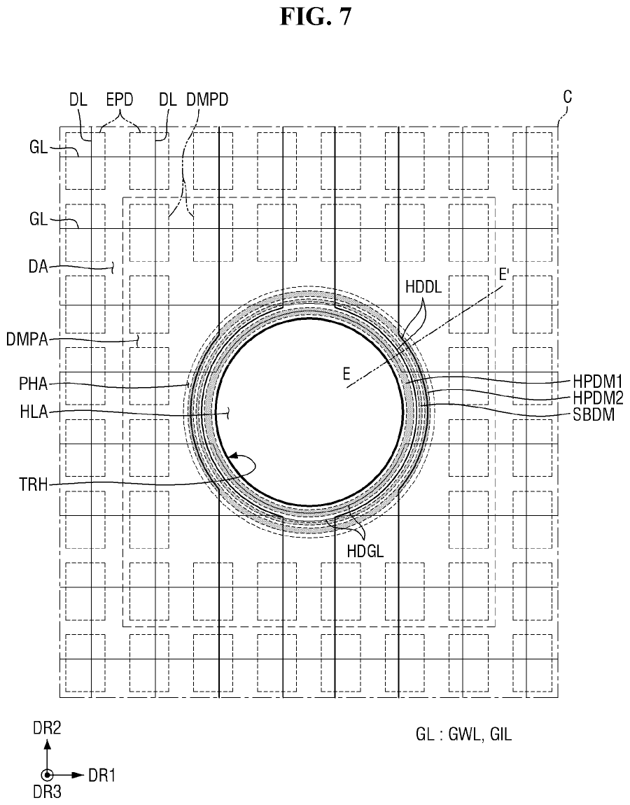

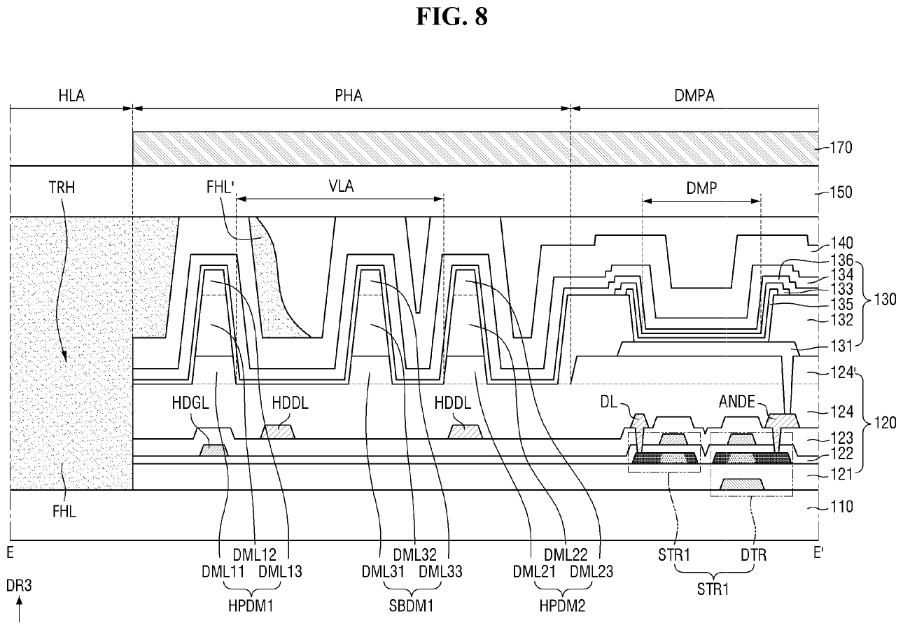

The hole area HLA may overlap an optical element located below the support substrate 110. Accordingly, a light transmitting hole (TRH in FIGS. 7 and 8) that provides a light incident path or a light exit path for the optical element may be located in the hole area HLA.

A hole peripheral dam (HPDM1 in FIGS. 7 and 8) and a second hole peripheral dam (HPDM2 in FIGS. 7 and 8) having a ring shape surrounding a periphery of the hole area HLA may be located in the hole peripheral area PHA.

In addition, bypass lines (HDGL and HDDL in FIG. 7) that intersect the hole area HLA and the hole peripheral area PHA may be located in the hole peripheral area PHA.

As illustrated in FIGS. 1 and 3, the support substrate 110 may further include a sub-area SBA protruding from one side of the main area MA.

The sub-area SBA may be an area protruding from the non-display area NDA of the main area MA to one side in the second direction DR2.

As a portion of the sub-area SBA is deformed into a curved shape, another portion of the sub-area SBA may be located on a rear surface of the display device 100.

FIGS. 2 and 3 illustrate the display device 100 with a portion of the sub-area SBA curved.

Referring to FIG. 3, the display device 100 according to some embodiments includes a support substrate 110, a circuit layer 120 located on the support substrate 110, an element layer 130 located on the circuit layer 120, a capping layer 140 located on the element layer 130, and an encapsulation substrate 150 located on the capping layer 140 and bonded to the support substrate 110.

The display device 100 according to some embodiments may further include a sealing layer 160 located in the non-display area NDA and bonding the support substrate 110 and the encapsulation substrate 150 to each other.

The support substrate 110 may be provided in the form of a rigid flat plate. Alternatively, the support substrate 110 may also be provided in the form of a flexible flat plate that is easily deformed, such as bending, folding, or rolling.

The support substrate 110 may be made of an insulating material such as glass, quartz, or polymer resin.

The encapsulation substrate 150 may face one surface of the support substrate 110 and may be bonded to the support substrate 110 through the sealing layer 160.

The encapsulation substrate 150 may be provided in the form of a rigid flat plate.

The encapsulation substrate 150 may be made of a material that has light-

transmitting and insulating properties. As an example, the encapsulation substrate 150 may be made of any one of glass, quartz, and polymer resin.

The sealing layer 160 may be located in the non-display area NDA between the support substrate 110 and the encapsulation substrate 150 and may have a frame shape surrounding a periphery of the display area DA.

The sealing layer 160 may be made of an organic material having adhesiveness. As an example, the sealing layer 160 may be made of epoxy-based resin.

As a result, the support substrate 110 and the encapsulation substrate 150 are bonded to each other by the sealing layer 160, and a space between the support substrate 110 and the encapsulation substrate 150 may be sealed.

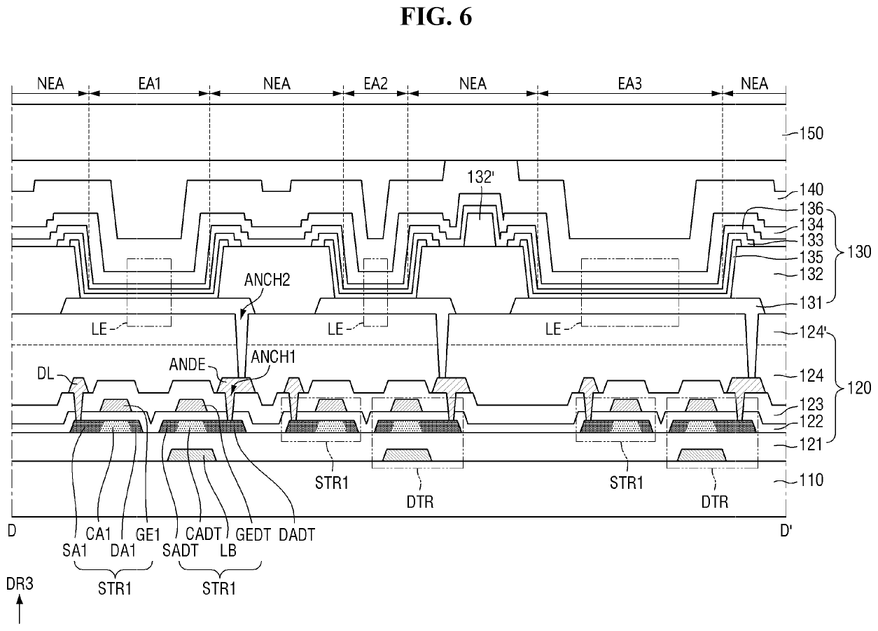

Referring to FIG. 4, the display area DA of the support substrate 110 of the display device 100 according to some embodiments may include light emitting areas EA. In addition, the display area DA may further include a non-light emitting area (NEA in FIG. 6), which is a separation area between the light emitting areas EA.

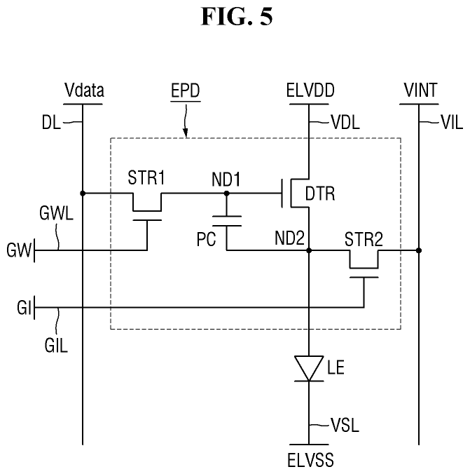

Light emitting pixel drivers EPD each corresponding to the light emitting areas EA may be arranged in the display area DA in parallel with each other in the first direction DR1 and the second direction DR2. The light emitting pixel drivers EPD may be electrically connected to light emitting elements (LE in FIGS. 5 and 6) of the element layer 130 each located in the light emitting areas EA.

The light emitting areas EA may have a rhombic planar shape or a rectangular planar shape. However, this is only an example, and the planar shape of the light emitting areas EA according to some embodiments is not limited to that illustrated in FIG. 4. That is, the light emitting areas EA may have a polygonal planar shape such as a square, pentagon, or hexagon, or a circular or oval planar shape including curved edges.

The light emitting areas EA may include first light emitting areas EA1 that

emit light of a first color in a wavelength band (e.g., a set or predetermined wavelength band), second light emitting areas EA2 that emit light of a second color in a wavelength band lower than that of the first color, and third light emitting areas EA3 that emit light of a third color in a wavelength band lower than that of the second color.

As an example, the first color may be red in a wavelength band in a range of (or approximately in a range of) 600 nm to 750 nm. The second color may be green in a wavelength band in a range of (or approximately in a range of) 480 nm to 560 nm. The third color may be blue in a wavelength band in a range of (or approximately in a range of) 370 nm to 460 nm.

The first light emitting areas EA1 and the third light emitting areas EA3 may be alternately arranged in at least one of the first direction DR1 or the second direction DR2.

The second light emitting areas EA2 may be arranged to be parallel to each other in at least one of the first direction DR1 or the second direction DR2.

In addition, the second light emitting areas EA2 may be adjacent to the first light emitting areas EA1 and the third light emitting areas EA3 in diagonal directions DR4 and DR5 intersecting the first and second directions DR1 and DR2.

Pixels PX that display each luminance and color may be provided by the first light emitting area EA1, the second light emitting area EA2, and the third light emitting area EA3 adjacent to each other among the light emitting areas EA.

In other words, the pixels PX may be basic units that display various colors, including white, at a luminance (e.g., a set or predetermined luminance).

Each of the pixels PX may include at least one first light emitting area EA1, at least one second light emitting area EA2, and at least one third light emitting area EA3 adjacent to each other. Accordingly, each of the pixels PX may display various colors through mixing of light emitted from the first, second, and third light emitting areas EA1, EA2, and EA3 adjacent to each other.

As illustrated in FIG. 3, the element layer 130 may include light emitting elements (LE in FIGS. 5 and 6) each located in the light emitting areas EA.

The circuit layer 120 may include light emitting pixel drivers EPD electrically connected to the light emitting elements LE, respectively, and lines electrically connected to the light emitting pixel drivers EPD.

FIG. 5 is an equivalent circuit diagram illustrating an example of a light emitting pixel driver of FIG. 4 according to some embodiments.

Referring to FIG. 5, one of the light emitting elements LE of the element layer 130 may be electrically connected between one of the light emitting pixel drivers EPD of the circuit layer 120 and a second power ELVSS.

That is, an anode electrode (131 in FIG. 6) of the light emitting element LE may be electrically connected to the light emitting pixel driver EPD, and the second power ELVSS having a lower voltage level than a first power ELVDD may be applied to a cathode electrode (134 in FIG. 6) of the light emitting element LE.

The circuit layer 120 may include data lines DL that transmit a data signal Vdata to the light emitting pixel drivers EPD, a first power line VDL that transmits the first power ELVDD, and an initialization power line VIL that transmits an initialization power VINT.

The circuit layer 120 may include gate lines (GL in FIG. 7) including a scan write line GWL that transmits a scan write signal GW and a scan initialization line GIL that transmits a scan initialization signal GI.

One light emitting pixel driver EPD of the circuit layer 120 may include a driving transistor DTR that generates a driving current for driving the light emitting element LE, two or more transistors STR1 to STR6 electrically connected to the driving transistor DTR, and at least one pixel capacitor PC.

The driving transistor DTR is connected in series with the light emitting element LE between the first power ELVDD and the second power ELVSS.

That is, a first electrode (e.g., a source electrode) of the driving transistor DTR may be electrically connected to the first power line VDL. In addition, a second electrode (e.g., a drain electrode) of the driving transistor DTR may be electrically connected to the anode electrode 131 of the light emitting element LE.

The pixel capacitor PC may be located between a first node ND1 and a second node ND2. The first node ND1 is a contact point between a gate electrode of the driving transistor DTR and a second transistor STR2. The second node ND2 is a contact point between the second electrode of the driving transistor DTR and the light emitting element LE.

That is, the pixel capacitor PC may be charged with the data signal Vdata transmitted to the first node ND1 through a turned-on first transistor STR1.

The first transistor STR1 may be electrically connected between the gate electrode of the driving transistor DTR and the data line DL.

The first transistor STR1 may be turned on by the scan write signal GW of the scan write line GWL.

When the data signal Vdata of the data line DL is transmitted to the first node ND1 through the turned-on first transistor STR1, a potential of the gate electrode of the driving transistor DTR is changed to the data signal Vdata, and as a result, a voltage difference between the gate electrode of the driving transistor DTR and the first electrode of the driving transistor DTR may become greater than a threshold voltage. Accordingly, a drain-source current of the driving transistor DTR corresponding to the data signal Vdata may generated and supplied as a driving current of the light emitting element LE.

The second transistor STR2 may be electrically connected between the anode electrode of the light emitting element LE and the initialization voltage line VIL.

The second transistor STR2 may be turned on by the scan initialization signal GI of the scan initialization line GIL.

When the second transistor STR2 is turned on, a potential of the anode electrode of the light emitting element LE may be initialized to an initialization voltage VINT of the initialization voltage line VIL.

As illustrated in FIG. 5, the driving transistor DTR, the first transistor STR1, and the second transistor STR2 may be prepared as P-type MOSFETs. However, this is only an example, and at least one of the driving transistor DTR, the first transistor STR1, or the second transistor STR2 may also be provided as an N-type MOSFET.

Although FIG. 5 illustrates various components, embodiments according to the present disclosure are not limited thereto, and according to some embodiments, there may be additional components or fewer components without departing from the spirit and scope of embodiments according to the present disclosure.

FIG. 6 is a cross-sectional view taken along the line D-D′ of FIG. 4.

FIG. 6 is a cross-sectional view illustrating the driving transistor DTR, the first transistor STR1, and the light emitting element LE of FIG. 5 according to some embodiments.

Referring to FIG. 6, the circuit layer 120 of the display device 100 according to some embodiments may include a buffer layer 121 covering the support substrate 110, semiconductor layers CADT, SADT, DADT, CA1, SA1, and DA1 located on the buffer layer 121, a gate insulating layer 122 covering the semiconductor layers, gate conductive layers GEDT and GE1 located on the gate insulating layer 122, an interlayer insulating layer 123 covering the gate conductive layers, source/drain conductive layers ANDE and DL located on the interlayer insulating layer 123, a first planarization layer 124 covering the source/drain conductive layers, and a second planarization layer 124′ located on the first planarization layer 124.

According to some embodiments, the circuit layer 120 may further include a light blocking layer LB located on the support substrate 110 and covered with the buffer layer 121.

The driving transistor DTR may include a channel portion CADT, a source portion SADT, and a drain portion DADT located on the semiconductor layer on the buffer layer 121, and a gate electrode GEDT located on the gate conductive layer on the gate insulating layer 122 and overlapping the channel portion CADT.

The channel portion CADT of the driving transistor DTR may overlap the light blocking layer LB.

The gate electrode GEDT of the driving transistor DTR may be electrically connected to the first transistor STR1.

The source portion SADT of the driving transistor DTR is the first electrode of the driving transistor DTR and may be electrically connected to the first power line VDL.

As an example, the first power line VDL may be located on the source/drain conductive layer on the interlayer insulating layer 123.

As an example, the pixel capacitor PC may be provided by an overlap area between the gate electrode GEDT of the driving transistor DTR and the first power line VDL.

The drain portion DADT of the driving transistor DTR is the second electrode of the driving transistor DTR, and may be electrically connected to the anode electrode 131 of the element layer 130 through an anode connection electrode ANDE.

The anode connection electrode ANDE may be located on the source/drain conductive layer on the interlayer insulating layer 123.

The anode connection electrode ANDE may be electrically connected to the drain portion DADT of the driving transistor DTR through a first anode connection hole ANCH1 penetrating through the interlayer insulating layer 123 and the gate insulating layer 122.

The first transistor STR1 may include a channel portion CA1, a source portion SA1, and a drain portion DA1 located on the semiconductor layer on the buffer layer 121, and a gate electrode GE1 located on the gate conductive layer on the gate insulating layer 122 and overlapping the channel portion CA1.

The gate electrode GE1 of the first transistor STR1 may be provided as a portion of the scan write line GWL.

The source portion SA1 of the first transistor STR1 is the first electrode of the first transistor STR1 and may be electrically connected to the data line DL.

The data line DL may be located on the source/drain conductive layer on the interlayer insulating layer 123.

The data line DL may be electrically connected to the source portion SA1 of the first transistor STR1 through a connection hole penetrating through the interlayer insulating layer 123 and the gate insulating layer 122.

The drain portion DA1 of the first transistor STR1 is the second electrode of the first transistor STR1 and may be electrically connected to the gate electrode GEDT of the driving transistor DTR.

The first planarization layer 124 and the second planarization layer 124′ may be provided together through one deposition process and one mask process. That is, a conductive layer may not be located between the first planarization layer 124 and the second planarization layer 124′.

Because the second transistor STR2 is provided with substantially the same structure as the first transistor STR1, except that it is electrically connected between the initialization voltage line VIL and the anode connection electrode ANDE, some redundant description may be omitted below.

The element layer 130 may be located on the second planarization layer 124′.

The element layer 130 may include an anode electrode 131 located on the second planarization layer 124′, a pixel defining layer 132 located on the second planarization layer 124′ and corresponding to the non-light emitting area NEA, which is a separation area between the light emitting areas EA, a spacer layer 132′ located on a portion of the pixel defining layer 132, a light emitting layer 133 located on the anode electrode 131, and a cathode electrode 134 located on the pixel defining layer 132 and the light emitting layer 133.

The element layer 130 may further include a first common layer 135 located between the anode electrode 131 and the light emitting layer 133, and a second common layer 136 located between the light emitting layer 133 and the cathode electrode 134.

That is, each of the light emitting elements LE of the element layer 130 may include a structure in which the first common layer 135, the light emitting layer 133, and the second common layer 136 are interposed between the anode electrode 131 and the cathode electrode 134.

The first common layer 135 may include a hole transporting layer corresponding to each of the light emitting areas EA and made of an organic material with hole transport properties. Alternatively, the first common layer 135 may further include a hole injection layer located between the anode electrode 131 and the hole transporting layer and made of an organic material with hole injection properties.

The second common layer 136 may include an electron transporting layer entirely corresponding to the light emitting areas EA and made of an organic material with electron transport properties. Alternatively, the second common layer 136 may further include an electron injection layer located between the electron transporting layer and the cathode electrode 134 and made of an organic material with electron injection properties.

The anode electrode 131, the light emitting layer 133, and the first common layer 135 may be located in each of the light emitting areas EA.

The cathode electrode 134 and the second common layer 136 may be entirely located in the display area DA including the light emitting areas EA.

The pixel defining layer 132 and the spacer layer 132′ may be provided together through one deposition process and one mask process.

The capping layer 140 covers the element layer 130. The capping layer 140 may be made of an organic insulating material.

The encapsulation substrate 150 may be located on the capping layer 140 and may be in contact with the capping layer 140.

The encapsulation substrate 150 may be supported by the spacer layers 132′ distributed in the display area DA and the sealing layer 160 in the non-display area NDA.

FIG. 7 is a layout view illustrating portion C of FIG. 2 according to some embodiments. FIG. 8 is a cross-sectional view taken along the line E-E′ of FIG. 7 according to some embodiments.

The support substrate 110 of the display device 100 according to some embodiments includes a main area MA corresponding to the display surface. The main area MA includes a display area DA in which the light emitting areas EA are arranged. The main area MA may further include a non-display area NDA, which is arranged around the display area DA and in which the light emitting areas EA are not arranged.

Referring to FIG. 7, the support substrate 110 of the display device 100 according to some embodiments may further include a hole area HLA surrounded by the main area MA, and a hole peripheral area located between the main area MA and the hole area HLA.

The hole area HLA may be surrounded by the main area MA by being located within the main area MA.

The hole peripheral area PHA may be an area surrounding the periphery of the hole area HLA.

As illustrated in FIGS. 7 and 8, the display device 100 according to some embodiments may include a first hole peripheral dam HPDM1 located in the hole peripheral area PHA and surrounding the periphery of the hole area HLA, a second hole peripheral dam HPDM2 located in the hole peripheral area PHA and surrounding the periphery of the first hole peripheral dam HPDM1, and an auxiliary dam SBDM1 located in a valley area VLA between the first hole peripheral area HPDM1 and the second hole peripheral dam HPDM2 of the hole peripheral area PHA.

According to some embodiments, the first hole peripheral dam HPDM1 may be arranged in a ring shape adjacent to the hole area HLA and surrounding the periphery of the hole area HLA.

According to some embodiments, the second hole peripheral dam HPDM2 may be arranged in a ring shape adjacent to the main area MA and surrounding the periphery of the first hole peripheral dam HPDM1.

The first hole peripheral dam HPDM1 and the second hole peripheral dam HPDM2 may be located on the first planarization layer 124.

The first hole peripheral dam HPDM1 may include a structure in which at least one dam layer DML11, DML12, and DML13 is stacked on the first planarization layer 124.

At least one dam layer DML11, DML12, and DML13 of the first hole peripheral dam HPDM1 may be located on the same layer as at least one of the second planarization layer 124′, the pixel defining layer 132, or the spacer layer 132′. As an example, the first hole peripheral dam HPDM1 may include a first dam layer DML11 located on the same layer as the second planarization layer 124′, a second dam layer DML12 located on the same layer as the pixel defining layer 132, and a third dam layer DML13 located on the same layer as the spacer layer 132′.

The second hole peripheral dam HPDM2 may include a structure in which at least one dam layer DML21, DML22, and DML23 is stacked on the first planarization layer 124.

At least one dam layer DML21, DML22, and DML23 of the second hole peripheral dam HPDM2 may be located on the same layer as at least one of the second planarization layer 124′, the pixel defining layer 132, or the spacer layer 132′. As an example, the second hole peripheral dam HPDM2 may include a first dam layer DML21 located on the same layer as the second planarization layer 124′, a second dam layer DML22 located on the same layer as the pixel defining layer 132, and a third dam layer DML23 located on the same layer as the spacer layer 132′.

A thickness of the second hole peripheral dam HPDM2 may be less than or equal to a total thickness of a portion of the display area DA where the second planarization layer 124′, the pixel defining layer 132, and the spacer layer 132′ are sequentially stacked, and may be greater than or equal to a thickness of the first hole peripheral dam HPDM1.

In this way, a portion of the encapsulation substrate 150 that overlaps the hole peripheral area PHA may be supported by at least the second hole peripheral dam HPDM2 among the first hole peripheral dam HPDM1 and the second hole peripheral dam HPDM2, and may not be lifted or protrude more than another portion of the encapsulation substrate 150 supported by the spacer layer 132′ of the display area DA.

According to some embodiments, the auxiliary dam SBDM1 may be arranged closer to the second hole peripheral dam HPDM2 among the first hole peripheral dam HPDM1 and the second hole peripheral dam HPDM2.

A thickness of the auxiliary dam SBDM1 may be less than or equal to the thickness of the second hole peripheral dam HPDM2.

The auxiliary dam SBDM1 may include a structure in which at least one dam layer DML31, DML32, and DML33 is stacked on the first planarization layer 124.

According to some embodiments, at least one dam layer DML31, DML32, and DML33 of the auxiliary dam SBDM1 may be located on the same layer as at least one of the second planarization layer 124′, the pixel defining layer 132, or the spacer layer 132′. As an example, the auxiliary dam SBDM1 may include a first dam layer DML31 located on the same layer as the second planarization layer 124′, a second dam layer DML32 located on the same layer as the pixel defining layer 132, and a third dam layer DML33 located on the same layer as the spacer layer 132′.

That is, according to some embodiments, the auxiliary dam SBDM1 may be arranged to have the same thickness as the second hole peripheral dam HPDM2.

In this way, the lifting defect of the encapsulation substrate 150 caused by the second hole peripheral dam HPDM2 may be reduced because a portion of the encapsulation substrate 150 that is sagged due to the sagging defect may be supported by the auxiliary dam SBDM1 rather than the second hole peripheral dam HPDM2 adjacent to the main area MA, even if the sagging defect of the encapsulation substrate 150 occurs in the valley area VLA.

Referring to FIG. 8, a light transmitting hole TRH penetrating through the circuit layer 120, the element layer 130, and the capping layer 140 may be located in the hole area HLA.

The light transmitting hole TRH may provide a light incident path or a light transmission path for an optical element located below the support substrate 110.

According to some embodiments, the display device 100 may include a hole filling layer FHL that fills the light transmitting hole TRH.

In the hole area HLA, as the circuit layer 120, the element layer 130, and the capping layer 140 are removed by the light transmitting hole TRH, the support substrate 110 and the encapsulation substrate 150 face each other. Accordingly, in the hole area HLA, the hole filling layer FHL may fill a space between the support substrate 110 and the encapsulation substrate 150.

Because the hole filling layer FHL may not only support a portion of the encapsulation substrate 150 that overlaps the hole area HLA, but also seal the light transmitting hole TRH, permeation of oxygen or moisture through the light transmitting hole TRH may be reduced.

A process of disposing the hole filling layer FHL may include a process of dropping a filling material in a liquid or gel state into the light transmitting hole TRH, and a process of diffusing the filling material in a liquid or gel state into an area surrounded by the first hole peripheral dam HPDM1.

In order for the hole filling layer FHL to completely fill the hole area HLA between the support substrate 110 and the encapsulation substrate 150, the amount of dropped filling material in a liquid or gel state may exceed the capacity of the hole area HLA between the support substrate 110 and the encapsulation substrate 150. Accordingly, in the process of diffusing the filling material in a liquid or gel state, the filling material in a liquid or gel state may be diffused into the valley area VLA of the hole peripheral area PHA beyond the first hole peripheral dam HPDM1.

According to some embodiments, the auxiliary dam SBDM1 may be arranged in a ring shape surrounding the periphery of the first hole peripheral dam HPDM1.

Accordingly, in the valley area VLA of the hole peripheral area PHA, the diffusion of the filling material may be blocked by the auxiliary dam SBDM1.

Accordingly, the hole filling layer FHL may be located in the area surrounded by the first hole peripheral dam HPDM1, and a portion FHL′ of the hole filling layer FHL may extend to an area between the first hole peripheral dam HPDM1 and the auxiliary dam SBDM1 in the valley area VLA.

In a process of disposing the first planarization layer 124 and the second planarization layer 124′, the second planarization layer 124′ in the hole peripheral area PHA may be partially removed using a halftone mask.

That is, the rest of the second planarization layer 124′ in the hole peripheral area PHA except for the first dam layers DML11, DML21, and DML31 may be removed.

In addition, the second common layer 136 and the cathode electrode 134 extend to the hole peripheral area PHA because of being arranged throughout the display area DA and removed by the light transmitting hole TRH in the hole area HLA.

As a result, in the valley area VLA of the hole peripheral area PHA, the second common layer 136 may be located on the first planarization layer 124, the first hole peripheral dam HPDM1, the second hole peripheral dam HPDM2, and the auxiliary dam SBDM1 that are exposed, and the cathode electrode 134 may be located on the second common layer 136.

According to some embodiments, the display area DA of the support substrate 110 may include a dummy pixel area DMPA consisting of a portion in contact with the hole peripheral area PHA.

The dummy pixel area DMPA may further include dummy pixels DMP arranged in one or more columns and one or more rows around the hole peripheral area PHA.

The dummy pixels DMP do not emit light for image display and may be provided to widen a minimum gap between the hole peripheral area PHA and the light emitting areas EA of the display area DA.

In the same way that each of the light emitting areas EA corresponds to the light emitting pixel driver EPD and the light emitting element LE, each of the dummy pixels DMP may correspond to a dummy pixel driver DMPD and a dummy light emitting element.

As such, according to some embodiments, as the display area DA includes the dummy pixel area DMPA, the hole filling layer FHL may not extend to the light emitting areas EA of the display area DA, even if the amount of dropped filling material in a liquid or gel state exceeds the capacity of the hole area HLA and the capacity of the valley area VLA. As a result, deterioration in display quality due to the hole filling layer FHL may be prevented.

As illustrated in FIGS. 7 and 8, the circuit layer 120 of the display device 100 according to some embodiments may include gate lines GL extending in the first direction DR1 and data lines DL extending in the second direction DR2.

The gate lines GL may include a scan write line GWL and a scan initialization line GIL connected to the gate electrodes of the transistors STR1 and STR2.

According to some embodiments, a portion of the circuit layer 120 that overlaps the hole area HLA is removed by the light transmitting hole TRH, the circuit layer 120 may further include lines HDGL and HDDL located in the hole peripheral area PHA and bypassing the periphery of the hole area HLA.

That is, the circuit layer 120 may include hole bypass gate lines HDGL connected to some of the gate lines GL intersecting the hole area HLA and the hole peripheral area PHA among the gate lines GL, and hole bypass data lines HDDL connected to some of the data lines DL intersecting the hole area HLA and the hole peripheral area PHA among the data lines DL.

The hole bypass gate lines HDGL and the hole bypass data lines HDDL may be located in the hole peripheral area PHA and may extend along the periphery of the hole area HLA.

The hole bypass gate lines HDGL and the hole bypass data lines HDDL may overlap the first hole peripheral dam HPDM1, the second hole peripheral dam PHDM2, and the auxiliary dam SBDM1 located in the hole peripheral area PHA.

According to some embodiments, the display device 100 may further include a light blocking portion 170 located on the encapsulation substrate 150 and overlapping the hole peripheral area PHA and the dummy pixel area DMPA.

The light blocking portion 170 may have a ring shape including a hole corresponding to the hole area HLA.

The light blocking portion 170 may include a metal material.

As described above, as the display device 100 according to some embodiments includes the auxiliary dam SBDM1 located in the valley area VLA, excessive sagging defect of the encapsulation substrate 150 in the valley area VLA may be prevented.

In other words, because the first hole peripheral dam HPDM1 is in contact with the hole filling layer FHL, the encapsulation substrate 150 may be sufficiently supported near the first hole peripheral dam HPDM1. On the other hand, because the second hole peripheral dam HPDM2 is spaced apart from the first hole peripheral dam

HPDM1 and the spacer layer 132′ in the display area DA, the encapsulation substrate 150 is supported only by the second hole peripheral dam HPDM2 near the second hole peripheral dam HPDM2, which may result in sagging or lifting defect of the encapsulation substrate 150.

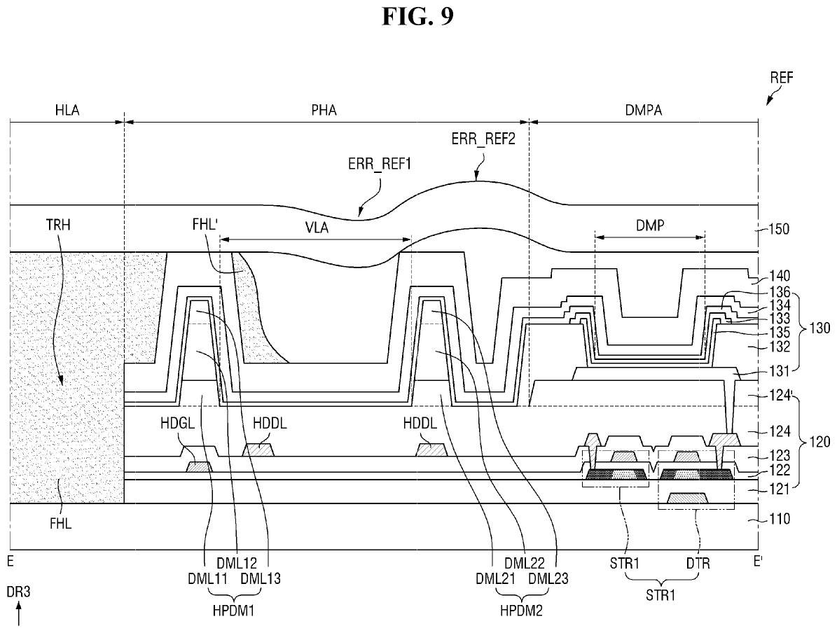

FIG. 9 is a cross-sectional view illustrating a hole area and a hole peripheral area according to a comparative example.

Referring to FIG. 9, a display device RFE according to a comparative example does not include the auxiliary dam SBDM1 located in the valley area VLA.

Accordingly, because the valley area VLA becomes an empty space, a portion of the encapsulation substrate 150 that overlaps the valley area VLA may not be supported by anything and may relatively easily droop.

That is, a sagging defect ERR_REF1 of the encapsulation substrate 150 may occur.

In addition, as a reaction to the excessive sagging defect ERR_REF1 of the encapsulation substrate 150, a lifting defect ERR_REF2 may be caused in which the encapsulation substrate 150 protrudes convexly from the edge of the hole peripheral area PHA adjacent to the display area DA and is separate from the capping layer 140.

In contrast, the display device 100 according to some embodiments includes the auxiliary dam SBDM1 located in the valley area VLA.

The auxiliary dam SBDM1 is adjacent to the second hole peripheral dam HPDM2, and is formed to have a thickness less than or equal to a thickness of the second hole peripheral dam HPDM2.

Accordingly, the encapsulation substrate 150 may be supported by the second hole peripheral dam HPDM2 and the auxiliary dam SBDM1 near the second hole peripheral dam HPDM2.

Therefore, the sagging and lifting defects of the encapsulation substrate 150 may be prevented by the auxiliary dam SBDM1, and thus the yield and quality uniformity of the display device 100 may be improved.

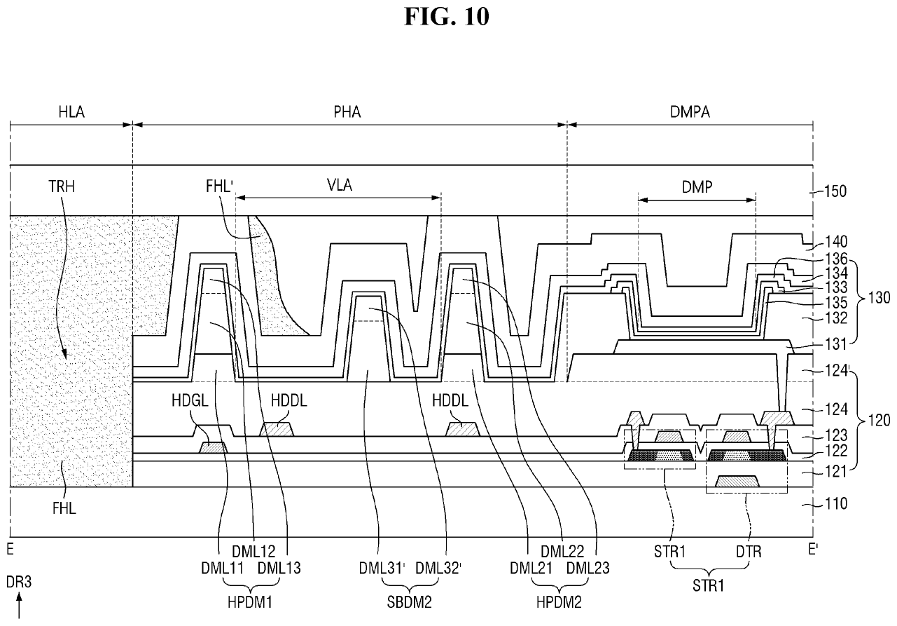

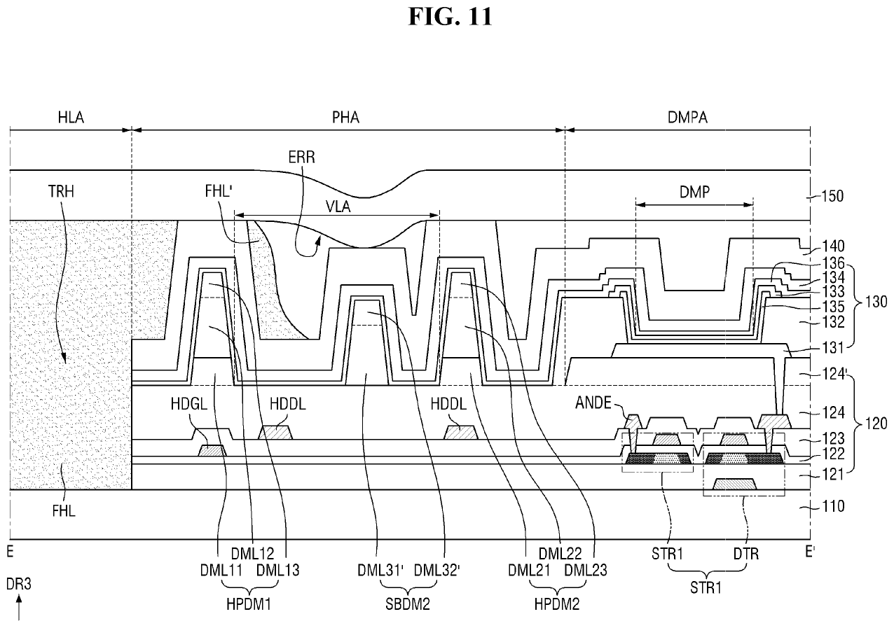

FIG. 10 is a cross-sectional view taken along line E-E′ of FIG. 7 according to some embodiments. FIG. 11 is a cross-sectional view illustrating a function of an auxiliary dam according to some embodiments.

Referring to FIG. 10, because a display device 100 according to some embodiments is substantially the same as that of the embodiments illustrated in FIGS. 1 to 8, except that at least one dam layer DML31′ and DML32′) of the auxiliary dam SBDM2 is located on the same layer as at least one of the pixel defining layer 132 or the spacer layer 132′, some redundant description may be omitted below

As illustrated in FIG. 10, the auxiliary dam SBDM2 according to some embodiments may include a first dam layer DML31′ located on the same layer as the pixel defining layer 132, and a second dam layer DML32 located on the same layer as the spacer layer 132′.

That is, according to some embodiments, because the auxiliary dam SBDM2 does not include a dam layer located on the same layer as the second planarization layer 124′ unlike the second hole peripheral dam HPDM2, a thickness of the auxiliary dam SBDM2 is smaller than the thickness of the second hole peripheral dam HPDM2.

Accordingly, the auxiliary dam SBDM2 may be spaced further away from the encapsulation substrate 150 than the first hole peripheral dam HPDM1 and the second hole peripheral dam HPDM2, because the encapsulation substrate 150 is supported only by the first hole peripheral dam HPDM1 and the second hole peripheral dam HPDM2 when a portion of the encapsulation substrate 150 that overlaps the valley area VLA maintains a flat shape, like the other portion of the encapsulation substrate 150 that overlaps the display area DA. That is, the auxiliary dam SBDM2 may not support the encapsulation substrate 150.

However, as illustrated in FIG. 11, when a portion of the encapsulation substrate 150 that overlaps the valley area VLA does not maintain a flat shape and is sagged, the sagged portion ERR of the encapsulation substrate 150 may be supported by the auxiliary dam SBDM2.

Therefore, according to some embodiments, an excessive sagging defect of the encapsulation substrate 150 may be prevented by the auxiliary dam SBDM2. That is, the auxiliary dam SBDM2 according to some embodiments may function to prevent the excessive sagging defect of the encapsulation substrate 150 by supporting the sagged portion ERR of the encapsulation substrate 150.

In addition, according to some embodiments, because the auxiliary dam SBDM2 is formed to have the thickness smaller than the second hole peripheral dam HPDM2, the lifting defect of the encapsulation substrate 150 caused by the auxiliary dam SBDM2 may be prevented.

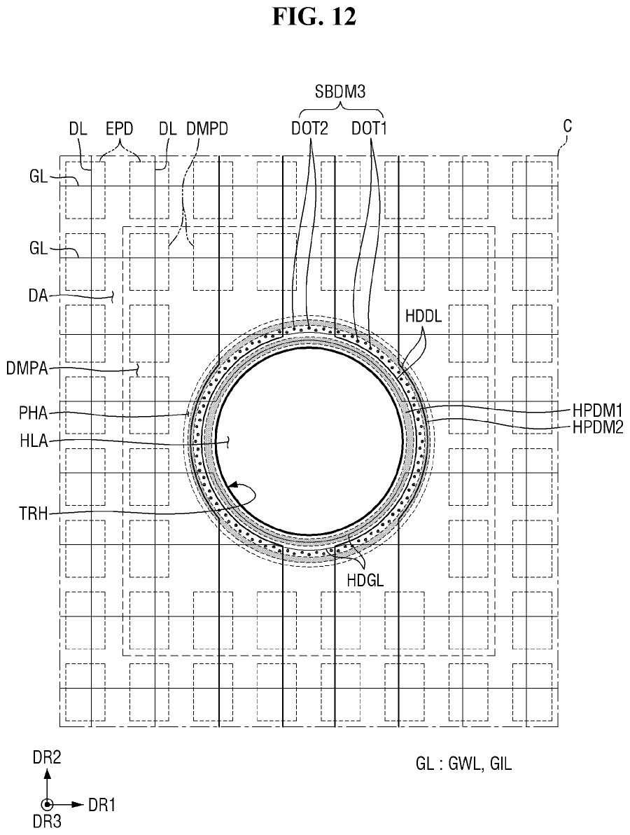

FIG. 12 is a layout view illustrating portion C of FIG. 2 according to some embodiments.

Referring to FIG. 12, a display device 100 according to some embodiments is substantially the same as that of the embodiments illustrated in FIGS. 1 to 8, 10, and 11, except that an auxiliary dam SBDM3 includes dot-shaped pillars DOT1 and DOT2 arranged along the periphery of the first hole peripheral dam HPDM1 and spaced apart from each other.

According to some embodiments as illustrated in FIG. 12, the auxiliary dam SBDM3 may not be arranged in a ring shape surrounding the periphery of the first hole peripheral dam HPDM1, but may include a structure in which dot-shaped pillars DOT1 and DOT2 spaced apart from each other are arranged.

As illustrated in FIGS. 8 and 10, each of the pillars DOT1 and DOT2) of the auxiliary dam SBDM3 may include a structure in which at least one dam layer DML31, DML32, and DML33 (DML31′ and DML32′) is stacked on the first planarization layer 124.

The auxiliary dam SBDM3 may include first pillars DOT1 arranged in a circle adjacent to the first hole peripheral dam HPDM1, and second pillars DOT2 arranged in a circle adjacent to the second hole peripheral dam HPDM2.

However, this is only an example, and the arrangement of the pillars DOT1 and DOT2 of the auxiliary dam SBDM3 may not be limited to that illustrated in FIG. 12. That is, the pillars DOT1 and DOT2 of the auxiliary dam SBDM3 may also be arranged in one or more circles sequentially surrounding the periphery of the first hole peripheral dam HPDM1.

In this way, when the auxiliary dam SBDM3 includes the dot-shaped pillars DOT1 and DOT2, an area allocated to the arrangement of the auxiliary dam SBDM3 may be reduced compared to the auxiliary dam SBDM having the ring shape. Therefore, as a decrease in capacity of the valley area VLA due to the auxiliary dam SBDM3 is reduced, the capacity of the hole filling layer FHL that may be accommodated in the valley area VLA may be increased.

The characteristics of embodiments according to the present disclosure are not restricted to those set forth herein. The above and other characteristics of embodiments according to the present disclosure will become more apparent to one of ordinary skill in the art to which the present disclosure pertains by referencing the appended claims, and their equivalents.

What is claimed is:

1. A display device comprising:
a support substrate including a main area including a display area in which light emitting areas are arranged, a hole area surrounded by the main area, and a hole peripheral area between the hole area and the main area;
a circuit layer on the support substrate;
an element layer on the circuit layer;
a capping layer on the element layer;
an encapsulation substrate on the capping layer and bonded to the support substrate;
a first hole peripheral dam in the hole peripheral area and surrounding a periphery of the hole area;
a second hole peripheral dam in the hole peripheral area and surrounding a periphery of the first hole peripheral dam; and
an auxiliary dam in a valley area of the hole peripheral area between the first hole peripheral dam and the second hole peripheral dam.

2. The display device of claim 1, wherein the second hole peripheral dam is adjacent to the main area, and
the auxiliary dam is closer to the second hole peripheral dam among the first hole peripheral dam and the second hole peripheral dam.

3. The display device of claim 2, wherein the first hole peripheral dam is arranged in a ring shape surrounding the periphery of the hole area,
the auxiliary dam is arranged in a ring shape surrounding the periphery of the first hole peripheral dam, and
the second hole peripheral dam is arranged in a ring shape surrounding a periphery of the auxiliary dam.

4. The display device of claim 2, wherein the auxiliary dam includes dot-shaped pillars arranged along the periphery of the first hole peripheral dam and spaced apart from each other.

5. The display device of claim 2, further comprising:
a light transmitting hole in the hole area and penetrating through the circuit layer, the element layer, and the capping layer; and
a hole filling layer in an area surrounded by the first hole peripheral dam and filling the light transmitting hole.

6. The display device of claim 5, wherein a portion of the hole filling layer extends to an area between the first hole peripheral dam and the auxiliary dam.

7. The display device of claim 5, wherein the circuit layer includes:
a buffer layer covering the support substrate;
a gate insulating layer covering a semiconductor layer on the buffer layer;
an interlayer insulating layer covering a first conductive layer on the gate insulating layer;
a first planarization layer covering a second conductive layer on the interlayer insulating layer; and
a second planarization layer covering the first planarization layer,
the element layer includes:
anode electrodes respectively in the light emitting areas of the display area;
a pixel defining layer in a non-light emitting area, which is a spaced area between the light emitting areas, of the display area and covering an edge of each of the anode electrodes;
a spacer layer on a portion of the pixel defining layer;
light emitting layers on the anode electrodes; and
a cathode electrode on the light emitting layers, the pixel defining layer, and the spacer layer,
the capping layer covers the cathode electrode,
the first hole peripheral dam, the second hole peripheral dam, and the auxiliary dam each include a structure in which at least one dam layer is stacked on the first planarization layer,
at least one dam layer of the first hole peripheral dam is on a same layer as at least one of the second planarization layer, the pixel defining layer, or the spacer layer, and
at least one dam layer of the second hole peripheral dam is on a same layer as at least one of the second planarization layer, the pixel defining layer, or the spacer layer.

8. The display device of claim 7, wherein a thickness of the auxiliary dam is less than or equal to a thickness of the second hole peripheral dam, and
the encapsulation substrate contacts the capping layer and is supported by the auxiliary dam in the valley area.

9. The display device of claim 8, wherein at least one dam layer of the auxiliary dam is on a same layer as at least one dam layer of the second hole peripheral dam.

10. The display device of claim 8, wherein at least one dam layer of the auxiliary dam is on a same layer as at least one of the pixel defining layer or the spacer layer.

11. The display device of claim 8, wherein the first planarization layer and the second planarization layer are prepared together through a single mask process, and
the pixel defining layer and the spacer layer are prepared together through a single mask process.

12. A display device comprising:
a support substrate including a main area including a display area in which light emitting areas are arranged, a hole area surrounded by the main area, and a hole peripheral area between the hole area and the main area;
a circuit layer on the support substrate;
an element layer on the circuit layer;
a capping layer on the element layer;
an encapsulation substrate on the capping layer and bonded to the support substrate;
a first hole peripheral dam in the hole peripheral area and surrounding a periphery of the hole area;
a second hole peripheral dam in the hole peripheral area and surrounding a periphery of the first hole peripheral dam;
an auxiliary dam in a valley area of the hole peripheral area between the first hole peripheral dam and the second hole peripheral dam;
a light transmitting hole in the hole area and penetrating through the circuit layer, the element layer, and the capping layer; and
a hole filling layer in an area surrounded by the first hole peripheral dam and filling the light transmitting hole.

13. The display device of claim 12, wherein a thickness of the auxiliary dam is less than or equal to a thickness of the second hole peripheral dam, and
the encapsulation substrate contacts the capping layer and is supported by the auxiliary dam in the valley area.

14. The display device of claim 13, wherein the circuit layer includes:
a buffer layer covering the support substrate;
a gate insulating layer covering a semiconductor layer on the buffer layer;
an interlayer insulating layer covering a first conductive layer on the gate insulating layer;
a first planarization layer covering a second conductive layer on the interlayer insulating layer; and
a second planarization layer covering the first planarization layer,
the element layer includes:
anode electrodes respectively in the light emitting areas of the display area;
a pixel defining layer in a non-light emitting area, which is a spaced area between the light emitting areas, of the display area and covering an edge of each of the anode electrodes;
a spacer layer on a portion of the pixel defining layer and spaced apart from each other;
light emitting layers on the anode electrodes; and
a cathode electrode on the light emitting layers, the pixel defining layer, and the spacer layer,
the capping layer covers the cathode electrode,
the first hole peripheral dam, the second hole peripheral dam, and the auxiliary dam each include a structure in which at least one dam layer is stacked on the first planarization layer,
at least one dam layer of the first hole peripheral dam is on a same layer as at least one of the second planarization layer, the pixel defining layer, or the spacer layer, and
at least one dam layer of the second hole peripheral dam is on a same layer as at least one of the second planarization layer, the pixel defining layer, or the spacer layer.

15. The display device of claim 14, wherein at least one dam layer of the auxiliary dam is on a same layer as at least one dam layer of the second hole peripheral dam.

16. The display device of claim 14, wherein at least one dam layer of the auxiliary dam is on a same layer as at least one of the pixel defining layer or the spacer layer.

17. The display device of claim 14, wherein the second hole peripheral dam is adjacent to the main area, and
the auxiliary dam is closer to the second hole peripheral dam among the first hole peripheral dam and the second hole peripheral dam.

18. The display device of claim 17, wherein the first hole peripheral dam is arranged in a ring shape surrounding the periphery of the hole area,
the auxiliary dam is arranged in a ring shape surrounding the periphery of the first hole peripheral dam, and
the second hole peripheral dam is arranged in a ring shape surrounding a periphery of the auxiliary dam.

19. The display device of claim 17, wherein the auxiliary dam includes dot-shaped pillars arranged along the periphery of the first hole peripheral dam and spaced apart from each other.

20. The display device of claim 14, wherein the first planarization layer and the second planarization layer are prepared together through a single mask process, and
the pixel defining layer and the spacer layer are prepared together through a single mask process.
